(19) United States
(12) Patent Application Publication
(10) Pub. No.: US 2021/0242046 A1
(43) Pub. Date: Aug. 5, 2021

(54) CERAMIC HEATER

(71) Applicant: NGK INSULATORS, LTD., Nagoya-City (JP)

(72) Inventors: Daichi KUBOTA, Handa-City (JP); Norifumi SHIMAZU, Handa-City (JP)

(73) Assignee: NGK INSULATORS, LTD., Nagoya-City (JP)

(21) Appl. No.: 17/098,804

(22) Filed: Nov. 16, 2020

(30) Foreign Application Priority Data
Feb. 4, 2020 (JP) 2020-016784

(51) Int. Cl. H01L 21/67; H05B 3/28; H05B 1/02; H01L 21/683; H01J 37/32

(52) U.S. Cl. CPC H01L 21/67103; H05B 3/283; H05B 1/0233; H01L 21/6833; H01J 2237/2007; H01J 37/32724; H05B 2203/005; H01J 2237/3321; H01J 37/32082

(57) ABSTRACT

A ceramic heater includes a disc-shaped ceramic substrate that has a wafer placement surface and in which a substrate heater electrode is embedded. The ceramic heater includes a step portion and a step heater electrode. The step portion is annular and extends along an outer periphery of the ceramic substrate to surround the wafer placement surface. The step portion is higher than the wafer placement surface. The step heater electrode is embedded in the step portion. Electric power is supplied to the step heater electrode independently of the substrate heater electrode.

### BACKGROUND OF THE INVENTION

### 1. Field of the Invention

The present invention relates to a ceramic heater.

### 2. Description of the Related Art

An example of a known ceramic heater includes a disc-shaped ceramic insulating plate having an attachment surface to which a wafer is attached (for example, PTL 1). The ceramic insulating plate includes a disc-shaped central portion and an annular outer peripheral portion disposed outside and separated from the central portion with an annular heat insulation groove provided therebetween. A main heater and an outer peripheral heater, whose temperatures are independently controllable, are respectively embedded in the central portion and the outer peripheral portion. An outer peripheral ring is disposed on an upper surface of the outer peripheral portion. The outer peripheral ring is designed so that an upper surface of the outer peripheral ring and the attachment surface are at the same height when the outer peripheral ring is placed on the upper surface of the outer peripheral portion. When the wafer is placed on the ceramic insulating plate, the wafer comes into contact with the attachment surface and the upper surface of the outer peripheral ring.

### CITATION LIST

### Patent Literature

[PTL 1] Japanese Unexamined Patent Application Publication No. 2014-72355

### SUMMARY OF THE INVENTION

A large number of semiconductor chips can be produced from an outer peripheral portion of a wafer, and it is therefore desirable to perform a film forming step, for example, on the outer peripheral portion of the wafer with increased yield. To increase the chip yield in the outer peripheral portion of the wafer, it may be necessary to rapidly control the temperature of the outer peripheral portion of the wafer. However, a wafer placement table according to PTL 1 is configured such that the temperature of the outer peripheral portion of the wafer is controlled through the outer peripheral ring, and therefore the temperature of the outer peripheral portion of the wafer cannot be rapidly controlled.

The present invention has been made to solve the above-described problem, and a main object of the present invention is to enable rapid temperature control of the outer peripheral portion of the wafer.

A ceramic heater of the present invention includes a disc-shaped ceramic substrate that has a wafer placement surface and in which a substrate heater electrode is embedded, the ceramic heater includes:

a step portion that is annular and extends along an outer periphery of the ceramic substrate to surround the wafer placement surface, the step portion being higher than the wafer placement surface; and

a step heater electrode that is embedded in the step portion and to which electric power is supplied independently of the substrate heater electrode.

The ceramic heater includes the annular step portion that surrounds the wafer placement surface and that is higher than the wafer placement surface. The step heater electrode, to which electric power is supplied independently of the substrate heater electrode, is embedded in the step portion. Therefore, when heat is generated by the step heater electrode, an outer peripheral portion of a wafer placed on the wafer placement surface can be selectively heated from the side or obliquely from above. Accordingly, the temperature of the outer peripheral portion of the wafer can be rapidly controlled.

In the ceramic heater according to the present invention, the step heater electrode includes a plurality of step heater zone electrodes disposed one in each of a plurality of zones into which the step portion is divided in a circumferential direction. Electric power is independently supplied to each of the step heater zone electrodes. In this case, the temperature of the outer peripheral portion of the wafer can be rapidly controlled in a region where the temperature is to be controlled.

In the ceramic heater according to the present invention, the step portion may have a dividing groove disposed between the zones. In this case, heat conduction between the zones can be reduced by the dividing groove, so that the temperature of the outer peripheral portion of the wafer can be rapidly controlled with high accuracy in a region where the temperature is to be controlled.

In the ceramic heater according to the present invention, the step portion may have an annular groove in a region outside the step heater electrode. In this case, the annular groove provides thermal insulation so that dissipation of heat generated by the step heater electrode to the outside can be reduced. Therefore, the efficiency of rapid temperature control of the outer peripheral portion of the wafer can be increased.

In the ceramic heater according to the present invention, the ceramic substrate may be made of aluminum nitride. Since aluminum nitride is highly thermally conductive, heat generated by the substrate heater electrode is easily dissipated to the outside of the ceramic substrate, which makes it difficult to rapidly control the temperature of the outer peripheral portion of the wafer. Therefore, it is advantageous to apply the present invention.

The ceramic heater according to the present invention may further include an RF electrode embedded in the ceramic substrate. In this case, the ceramic heater according to the present invention may be used in a plasma process, such as plasma CVD. Even when the plasma density distribution is uneven around the outer peripheral portion of the wafer, the plasma density distribution can be corrected by rapidly controlling the temperature of the outer peripheral portion of the wafer.

The ceramic heater according to the present invention may further include an electrostatic electrode embedded in the ceramic substrate. In this case, the ceramic heater according to the present invention may be used as an electrostatic chuck. Even when the temperature of the wafer is uneven due to uneven chucking force applied to the outer peripheral portion of the wafer, the temperature of the outer peripheral portion of the wafer can be corrected.

### BRIEF DESCRIPTION OF THE DRAWINGS

FIG. 1 is a perspective view of a ceramic heater 10.

FIG. 2 is a sectional view of FIG. 1 taken along line A-A.

FIG. 3 is a sectional view of FIG. 1 taken along line B-B.

FIG. 4 is a graph showing the temperature distributions of the ceramic heater 10 and a ceramic heater according to the related art in a radial direction of a wafer W.

FIG. 5 is a sectional view of another example of the ceramic heater 10.

FIG. 6 is a sectional view of another example of the ceramic heater 10.

FIG. 7 is a sectional view of another example of the ceramic heater 10.

FIG. 8 is a sectional view of FIG. 7 taken along line C-C.

### DETAILED DESCRIPTION OF THE INVENTION

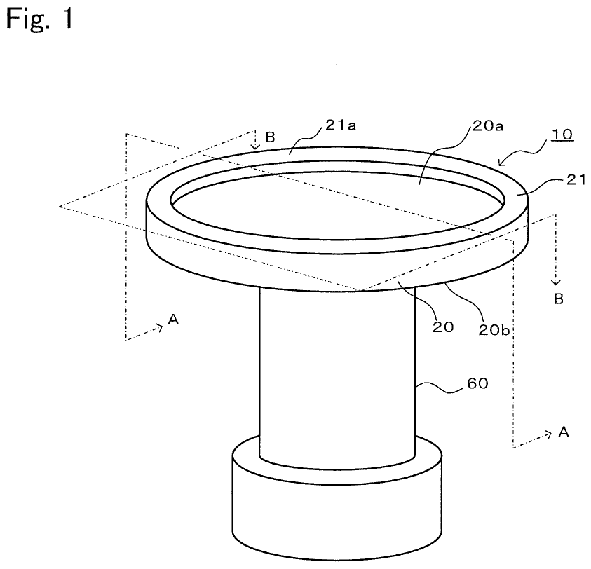

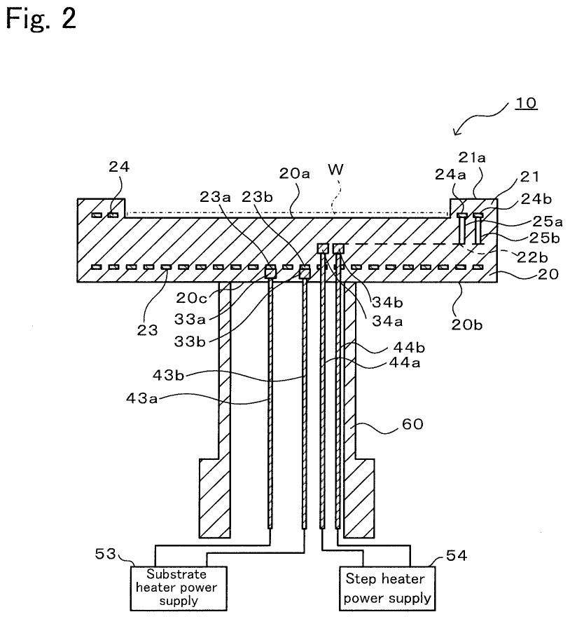

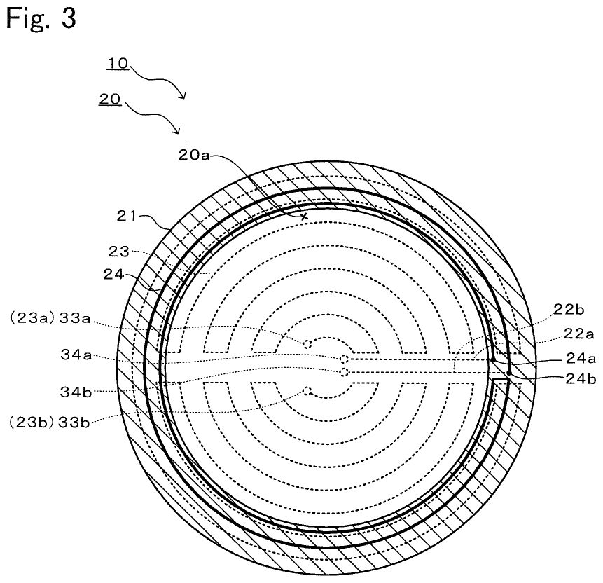

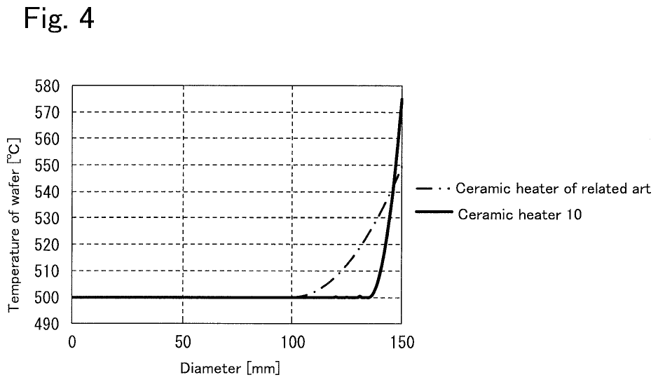

A preferred embodiment of the present invention will now be described with reference to the drawings. FIG. 1 is a perspective view of a ceramic heater 10. FIG. 2 is a sectional view of FIG. 1 taken along line A-A. FIG. 3 is a sectional view of FIG. 1 taken along line B-B (top view of a horizontal cross section of a step portion 21 at the height of a step heater electrode 24). FIG. 4 is a graph showing the temperature distributions of the ceramic heater 10 and a ceramic heater according to the related art in a radial direction of a wafer W.

The ceramic heater 10 is used to support and heat the wafer W to be subjected to CVD or etching using plasma. The ceramic heater 10 is disposed in and attached to a chamber (not shown) for a semiconductor process. The ceramic heater 10 includes a ceramic substrate 20 and a hollow ceramic shaft 60.

As illustrated in FIG. 1, the ceramic substrate 20 is a disc-shaped member made of a ceramic (for example, aluminum nitride). The diameter of the ceramic substrate 20 is not particularly limited, and may be, for example, about 300 mm. As illustrated in FIGS. 1 and 2, the ceramic substrate 20 has a wafer placement surface 20a on which the wafer W can be placed. The ceramic substrate 20 has a step portion 21 that extends along the outer periphery of the ceramic substrate 20 to surround the wafer placement surface 20a. The step portion 21 has an annular upper surface 21a that is parallel to the wafer placement surface 20a. The upper surface 21a is higher than the wafer placement surface 20a. The ceramic shaft 60 is joined to a central portion of a surface (back surface) 20b of the ceramic substrate 20 at a side opposite to the wafer placement surface 20a. As illustrated in FIGS. 2 and 3, a substrate heater electrode 23 is embedded in the ceramic substrate 20. In addition, a step heater electrode 24 is embedded in the step portion 21. The substrate heater electrode 23 and the step heater electrode 24 are each composed of, for example, a coil containing molybdenum, tungsten, or a carbide thereof as a main component.

The ceramic shaft 60 is a cylindrical member made of the same ceramic as the ceramic that forms the ceramic substrate 20. The top end surface of the ceramic shaft 60 is joined to the back surface 20b of the ceramic substrate 20 by diffusion bonding or thermal compression bonding (TCB). TCB is a known method of joining two members by compression bonding while the two members and a metal joining material placed between the two members are heated to a temperature less than or equal to the solidus temperature of the metal joining material.

As illustrated in FIG. 3, the substrate heater electrode 23 extends inside the ceramic substrate 20 from one end 23a, which is connected to an electrode terminal 33a, to the other end 23b, which is connected to an electrode terminal 33b, over substantially the entire region of the ceramic substrate 20 along a single continuous line with a plurality of bent portions. The pair of electrode terminals 33a and 33b are provided on the back surface 20b of the ceramic substrate 20 in a region 20c inside the ceramic shaft 60 (region inside the shaft). The pair of electrode terminals 33a and 33b are respectively joined to power supply bars 43a and 43b made of a metal (for example, Ni). The electrode terminals 33a and 33b are connected to a substrate heater power supply 53 by the power supply bars 43a and 43b, respectively. The power supply bars 43a and 43b are inserted through insulating tubes (not shown).

The step heater electrode 24 extends inside the step portion 21 from one end 24a to the other end 24b over substantially the entire region of the step portion 21 along a single continuous line with a plurality of bent portions. The one end 24a of the step heater electrode 24 is connected to a top end of a connection plug 25a shaped to extend in the vertical direction. The bottom end of the connection plug 25a is connected to an electrode terminal 34a by a lead line 22a shaped to extend in a horizontal direction. The other end 24b of the step heater electrode 24 is connected to a top end of a connection plug 25b shaped to extend in the vertical direction. The bottom end of the connection plug 25b is connected to an electrode terminal 34b by a lead line 22b shaped to extend in a horizontal direction. The pair of electrode terminals 34a and 34b are provided on the back surface 20b of the ceramic substrate 20 in the region 20c inside the shaft. The pair of electrode terminals 34a and 34b are respectively joined to power supply bars 44a and 44b made of a metal (for example, Ni). The electrode terminals 33a and 33b are connected to a step heater power supply 54 by the power supply bars 44a and 44b, respectively. The power supply bars 44a and 44b are inserted through insulating tubes (not shown).

An example of a method for manufacturing the ceramic heater 10 will now be described. First, a plurality of ceramic green sheets that are not fired and that contain aluminum nitride as a ceramic component are prepared. Then, the ceramic green sheets are subjected to a pattern printing process and a drying process to form various necessary patterns thereon. The patterns that are formed include patterns of the step heater electrode 24, the connection plugs 25a and 25b, the lead lines 22a and 22b, the substrate heater electrode 23, and the electrode terminals 33a, 33b, 34a, and 34b. The pattern printing process is performed by applying conductive paste for forming the patterns to the green sheets by using known screen printing technology. The conductive paste is selected based on the required characteristics of the patterns to be formed. The drying process is performed by using a known drying device. The thus-obtained green sheets are stacked in a predetermined order and compressed together into a single multilayer body under predetermined temperature and pressure conditions. The multilayer body is fired at a predetermined firing temperature. Then, the wafer placement surface 20a and the upper surface 21a are formed by a cutting or blasting process. Thus, the ceramic substrate 20 is obtained. The ceramic shaft 60 is obtained by, for example, forming a ceramic molded body by a mold casting method and firing the ceramic molded body. Subsequently, the ceramic substrate 20 and the ceramic shaft 60 are joined together. Finally, through holes are formed at positions corresponding to the electrode terminals 33a, 33b, 34a, and 34b in the region 20c inside the shaft, so that the electrode terminals 33a, 33b, 34a, and 34b are exposed in the region 20c inside the shaft. Then, the electrode terminals 33a, 33b, 34a, and 34b are respectively joined to the power supply bars 43a, 43b, 44a, 44b by a brazing material.

An example of use of the ceramic heater 10 will now be described. First, the ceramic heater 10 is disposed in a chamber (not shown), and the wafer W is placed on the wafer placement surface 20a. Then, a voltage applied to the substrate heater electrode 23 by the substrate heater power supply 53 is controlled so that the wafer W is heated by heat generated by the substrate heater electrode 23. Then, a surface of the wafer W is subjected to a film forming process. Then, the thickness of the film formed on the surface of the wafer W is measured by a film-thickness measurement device (not shown). The film on an outer peripheral portion of the wafer W may be thinner than the film on other portions, and experience shows that this may be because the temperature of the outer peripheral portion of the wafer W is lower than the temperature of other portions. Accordingly, the temperature of the outer peripheral portion of the wafer W is rapidly controlled so that the film on the outer peripheral portion of the wafer W and the film on other portions have the same thickness in the subsequent film forming processes. The rapid temperature control of the outer peripheral portion of the wafer W is performed by adjusting the voltage applied to the step heater electrode 24 by the step heater power supply 54 to control the amount of heat generated by the step heater electrode 24. As illustrated in FIG. 4, compared to the ceramic heater according to the related art, the ceramic heater 10 is capable of more rapidly controlling the temperature of the outer peripheral portion of the wafer W. The horizontal axis of the graph of FIG. 4 represents the distance from the center of the wafer W to the measurement point (diameter).

The above-described ceramic heater 10 according to the present embodiment includes the annular step portion 21 that surrounds the wafer placement surface 20a and that is higher than the wafer placement surface 20a. The step heater electrode 24, to which electric power is supplied independently of the substrate heater electrode 23, is embedded in the step portion 21. Therefore, when heat is generated by the step heater electrode 24, the outer peripheral portion of the wafer W placed on the wafer placement surface 20a can be selectively heated from the side or obliquely from above. Accordingly, the temperature of the outer peripheral portion of the wafer W can be rapidly controlled.

According to the ceramic heater 10 of the present embodiment, the ceramic substrate 20 is made of aluminum nitride and is therefore highly thermally conductive. Accordingly, heat generated by the substrate heater electrode 23 is easily dissipated to the outside of the ceramic substrate 20, which makes it difficult to rapidly control the temperature of the outer peripheral portion of the wafer W. Therefore, it is advantageous to provide the step heater electrode 24 to which electric power is independently supplied as described above.

The present invention is not limited to the above-described embodiments, and can be carried out by various modes as long as they belong to the technical scope of the invention.

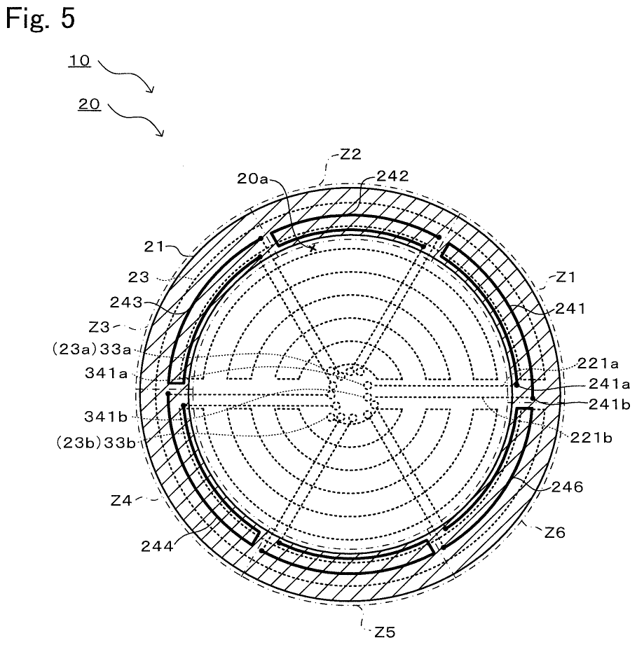

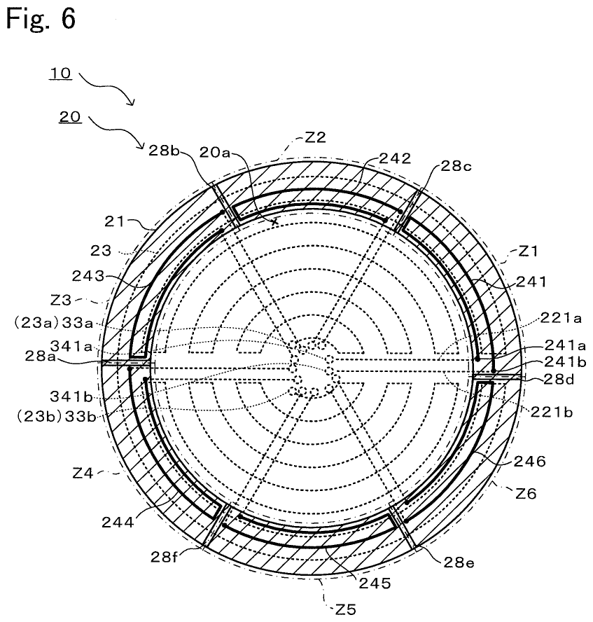

For example, although the step heater electrode 24 extends inside the step portion 21 over substantially the entire region thereof in the above-described embodiment, the step heater electrode 24 is not limited to this. As illustrated in FIG. 5, for example, the step heater electrode 24 may include step heater zone electrodes 241 to 246 that are respectively disposed in zones Z1 to Z6 into which the step portion 21 is divided in the circumferential direction. The step heater zone electrode 241 extends from one end 241a to the other end 241b over substantially the entire region of the zone Z1 along a single continuous line with a plurality of bent portions. The one end 241a of the step heater zone electrode 241 is connected to a top end of a connection plug shaped to extend in the vertical direction. The bottom end of the connection plug is connected to an electrode terminal 341a by a lead line 221a shaped to extend in a horizontal direction. The other end 241b of the step heater zone electrode 241 is connected to a top end of a connection plug shaped to extend in the vertical direction. The bottom end of the connection plug is connected to an electrode terminal 341b by a lead line 221b shaped to extend in a horizontal direction. The structures of the other step heater zone electrodes 242 to 246 are the same as that of the step heater zone electrode 241, and description thereof is thus omitted. In this case, electric power is individually supplied to the step heater zone electrodes 241 to 246. Thus, the temperature of the outer peripheral portion of the wafer W can be rapidly controlled in a region where the temperature is to be controlled. In FIG. 5, components that are the same as those in the above-described embodiment are denoted by the same reference signs. As illustrated in FIG. 6, dividing grooves 28a to 28f may be provided between the zones Z1 to Z6 that are adjacent to each other. In this case, heat conduction between the zones can be reduced by the dividing grooves 28a to 28f, so that the temperature of the outer peripheral portion of the wafer W can be rapidly controlled with high accuracy in a region where the temperature is to be controlled. In FIG. 6, components that are the same as those in the above-described embodiment are denoted by the same reference signs.

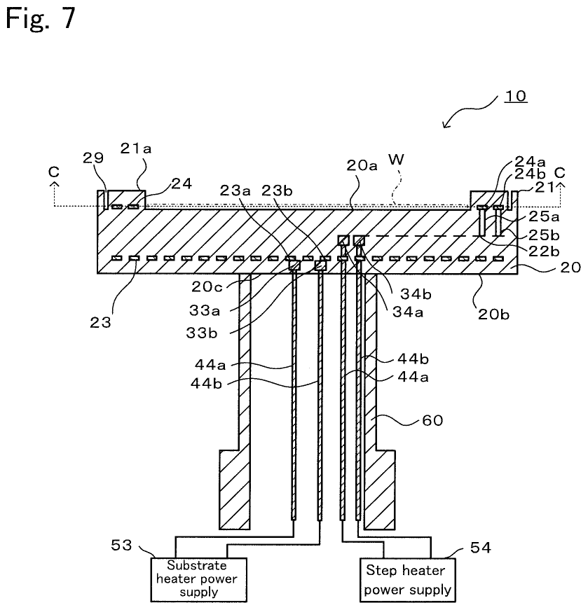

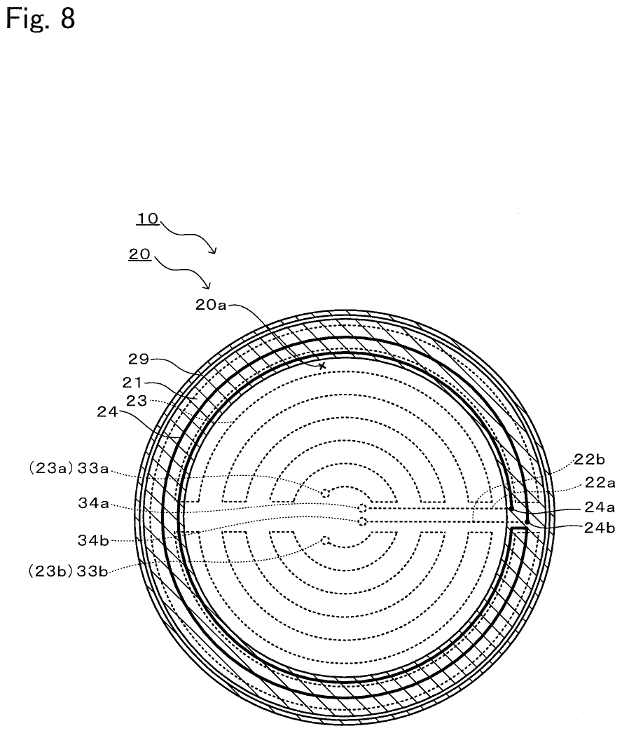

Although the step portion 21 has the step heater electrode 24 embedded therein in the above-described embodiment, the step portion 21 is not limited to this. As illustrated in FIGS. 7 and 8, for example, the step portion 21 may have an annular groove 29 in a region outside the step heater electrode 24. In this case, the annular groove 29 provides thermal insulation so that dissipation of heat generated by the step heater electrode 24 to the outside can be reduced. Therefore, the efficiency of rapid temperature control of the outer peripheral portion of the wafer W can be increased. In FIGS. 7 and 8, components that are the same as those in the above-described embodiment are denoted by the same reference signs.

Although the ceramic substrate 20 has the substrate heater electrode 23 and the step heater electrode 24 embedded therein in the above-described embodiment, the ceramic substrate 20 is not limited to this. For example, an RF electrode may be embedded in the ceramic substrate 20 in addition to the substrate heater electrode 23 and the step heater electrode 24. In this case, the ceramic heater 10 may be used in a plasma process, such as plasma CVD. Even when the plasma density distribution is uneven around the outer peripheral portion of the wafer W, the plasma density distribution can be corrected by rapidly controlling the temperature of the outer peripheral portion of the wafer W. Also, an electrostatic electrode may be embedded in the ceramic substrate 20 in addition to the substrate heater electrode 23 and the step heater electrode 24. In this case, the ceramic heater 10 may be used as an electrostatic chuck. Even when the temperature of the wafer W is uneven due to uneven chucking force applied to the outer peripheral portion of the wafer W, the temperature of the outer peripheral portion of the wafer W can be corrected.

Although the substrate heater electrode 23 and the step heater electrode 24 are coil-shaped in the above-described embodiment, the substrate heater electrode 23 and the step heater electrode 24 are not limited to this. For example, the substrate heater electrode 23 and the step heater electrode 24 may be printed patterns, and may be, for example, ribbon-shaped or mesh-shaped.

Although the substrate heater electrode 23 extends inside the ceramic substrate 20 over substantially the entire region thereof in the above-described embodiment, the substrate heater electrode 23 is not limited to this. For example, the substrate heater electrode 23 may include substrate heater zone electrodes, at least one of which is disposed in each of an inner zone that is circular and concentric with the ceramic substrate 20 and an outer zone that is annular and positioned outside the inner zone. In this case, electric power is individually supplied to the substrate heater zone electrodes. The inner zone and/or the outer zone may be divided into sector-shaped regions.

The present application claims priority from Japanese Patent Application No. 2020-016784 filed Feb. 4, 2020, the entire contents of which are incorporated herein by reference.

What is claimed is:

1. A ceramic heater including a disc-shaped ceramic substrate that has a wafer placement surface and in which a substrate heater electrode is embedded, the ceramic heater comprising:
a step portion that is annular and extends along a outer periphery of the ceramic substrate to surround the wafer placement surface, the step portion being higher than the wafer placement surface; and
a step heater electrode that is embedded in the step portion and to which electric power is supplied independently of the substrate heater electrode.

2. The ceramic heater according to claim 1,
wherein the step heater electrode includes a plurality of step heater zone electrodes disposed one in each of a plurality of zones into which the step portion is divided in a circumferential direction, and
electric power is independently supplied to each of the step heater zone electrodes.

3. The ceramic heater according to claim 2,
wherein the step portion has a dividing groove disposed between the zones.

4. The ceramic heater according to claim 1,
wherein the step portion has an annular groove in a region outside the step heater electrode.

5. The ceramic heater according to claim 1,
wherein the ceramic substrate is made of aluminum nitride.

6. The ceramic heater according to claim 1, further comprising:
an RF electrode embedded in the ceramic substrate.

7. The ceramic heater according to claim 1, further comprising:
an electrostatic electrode embedded in the ceramic substrate.
